(19) United States
(12) Patent Application Publication
(10) Pub. No.: US 2021/0333326 A1
(43) Pub. Date: Oct. 28, 2021

(54) Switch-Mode Based Interposer Enabling Self-Testing Of An MCM Without Known Good Die

(71) Applicant: Peter Shun Shen Wang, Gillette, NJ (US)

(72) Inventor: Peter Shun Shen Wang, Gillette, NJ (US)

(21) Appl. No.: 17/240,956

(22) Filed: Apr. 26, 2021

Related U.S. Application Data
(60) Provisional application No. 63/015,180, filed on Apr. 24, 2020.

(51) Int. Cl. G01R 31/3185; G01R 31/3187; G01R 31/319

(52) U.S. Cl. CPC G01R 31/318513; G01R 31/3187; G01R 31/31926; G01R 31/318558; G01R 31/31855; G01R 31/318552; G01R 31/318597; G01R 31/318536

(57) ABSTRACT

A Switching Mode Interposer (SMI) arrangement for boundary-scan testing of a Multi-Chip Module having a System-On-Chip, a Microprocessor Control Unit, and multiple chiplets-based devices including central processing units, graphical processing units, and/or memory devices disposed on a two-tiered interposer-substrate system. The SMI includes (a) a twin Test Access Port connected to a JTAG controller and configured to transmit test data in one direction (TAP-X) and an opposite direction (TAP-Y) along an Inter-Integrated Circuit (I2C) bus connected with the SOC, the MCU and the multiple devices, the test data being formatted according to IEEE 1149.1 or IEEE 1149.7 standard; and (b) a Mux/DeMux switch connected to the twin TAP and the I2C bus and responsive to the SOC or the MCU for selective switching of the test data along either the TAP-X or TAP-Y direction to a predetermined port associated with one of the multiple devices.

### CROSS REFERENCES TO RELATED APPLICATIONS

This application claims priority from U.S. Provisional Application No. 63/015,180 filed on Apr. 24, 2020, the disclosure of which is incorporated herein by reference in its entirety.

### FIELD OF INVENTION

The present invention relates to the field of determining manufacturing defects of JTAG compliant devices, and more particularly, to a method and an arrangement for a self-test method for testing a cluster of unknown dice in an MCM by a switch-mode based interposer using a unique self-test architecture that assigns a pair of indexed test heads, which steer test signals through a maze-like silicon base wherein a switching point allows the test signals to cross over at the intersection along a pair of bi-directional path ways.

### BACKGROUND OF THE INVENTION

It has been a common practice in the semiconductor chip manufacturing industry to fully test dice prior to their chip packaging onto circuit boards in order to avoid costly return of merchandise. A “Known Good Die” (KGD) is a fully tested chip prior to its placement in a multi-die package; such a classic approach is traditionally available to low pin count devices like RF and analog, passive devices in which a die is bonded on a ceramic substrate, and housed in a conventional metal can or plastic package. This process is time consuming and expensive and is generally only suitable for single die package. However, the advent of multi-chip modules (MCMs) renders this methodology impractical, if not obsolete. MCMs typically comprise dice with thousands of I/O pads that are stacked atop each other and surface mounted to a thin film ceramic, polyimide or silicon substrate making contacts via an array of eutectic solder bumping, i.e. gas vapor grown solder balls, and packaged into Ball Grid Array (BGA) based chip carrier. Applications of such packaging technology includes even more complicated IC designs such as System in Package (SiP) or System On Chip (SoC) wherein multiple dice are stacked in three-dimension and assembled in a complex package, which may be viewed as monolithic chips; especially when the chiplets have gained wide adoption in the computing industry, artificial intelligence (AI) technologies, and graphic intensive applications

Boundary scan testing, standardized in IEEE 1149.1 and its progeny (also known as JTAG and entitled “Standard Test Access Port and Boundary-Scan Architecture”), is employed to test the electrical integrity of a circuit or device without requiring the use of probes (i.e., a technique that uses metallic needles to physically contacting each I/O pin associated pads); instead JTAG uses silicon nails, to avoid destruction of needles, and each silicon nail has been embedded with boundary scan cells; in the case of solder bump based flip-chips implanted with such cells JTAG facilitates testing and programming on a bare die in lieu of a packaged chip.

Such circuit and device, however, must comply with the Boundary Scan Description Language (BSDL) specification, which specifies a device to have built-in boundary scan cells (or test registers), each pin mapped to a silicon nail based I/O port of the device, and a protocol that implements a serial communications interface for accessing chip associated identification (ID), Instruction Registers (IR), Data Registers (DR), Bypass Registers (BR) etc. The interface connects to an on-chip Test Access Port (TAP) that implements, in conjunction with a boundary scan test controller internally, to exercise a state machine protocol, to drive and sense the boundary scan cells that present a chip at logic bits of the gates, and an external controller that provides the various capabilities and properties to work with different JTAG compliant devices made by different IC manufacturers, which have chips with distinctive ID codes in 32 bits length. This internal TAP controller manipulates the test functions in each chip in response to TDI (Test Data In), TDO (Test Data Out), TMS (Test Mode Select), TCK (Test Clock), and an optional TRST (Test Reset) from an integrated circuit (IC) on a circuit board. Typically, multiple devices on a circuit board can have their JTAG lines daisy-chained together in a serial manner (e.g., Infrastructure test), and to test their associated netlists such as data, address and control buses in a parallel manner (e.g., Interconnection test), to thereby diagnose possible causes of errors such as open, short and bridging, etc. due to manufacturing defects, and to further debug firmware related error bits besides the defective on solder balls, bumping of the flip-chips, substrates of dice and an active interposer or passive interposer, etc.

The boundary scan cells (or test registers) are connected in a dedicated path around the device's boundary or periphery (hence the term “boundary scan captures”). The path creates a virtual access capability that circumvents the normal inputs and outputs, and that provides directional control of the test signals configured as a stream of digitized test data. A boundary scan cell may be a two-state or tri-state register and allows bidirectional signal paths and/or high impedance output.

Chip manufacturers provide BSDL files containing maps of the I/O's and properties of boundary scan cells and linkage bits of their chips. BSDL is a supplement to JTAG standard and is based on VHDL (Very High Speed Integrated Circuit Hardware Description Language), a hardware description language. However, the recent advance in SOC, which has no required BSDL files, employs Built-In-Self-Test (BIST) that only acquires two TAP signals, TCK and TMS, which are compliant with the JTAG standard and another standard: the compact JTAG (cJTAG) as per IEEE1149.7 rather than the commonly applied IEEE1149.1 standard.

Semiconductor back-end related unknown dies such as CPU, GPU based chiplets and their associated memory dices, have hindered the system design due to the newly promoted GPU and CPU in chiplet form which lack accountability when the traces are rerouted or redistributed based on the thin-film process or devices assembled on the interposer by transverse silicon via (TSV), and integrated with the stack-up DDRs, which may not be validated by the netlist or qualified by their Bill Of Material (BOM). All of these are prone to open, short, bridging, grounding and signal related cross talks, latent faults during manufacturing, resulting poor yielding and throughput, unless steps are taken to have the system check on its own dies, since they are not conveniently accessible to the chiplets within an MCM.

Given the increasingly compact 3D packaging of bare dice in an MCM without KGD, chip manufacturers cannot cost-effectively streamline their MCM manufacturing process in order to validate and guarantee the quality of MCMs. Heretofore, there is no prior art solution to the problem of making reliable MCMs with a newly developed approach by using a switch-mode interposer to run self-test, diagnose and trouble-shoot the substrate beside BIST on the interposer.

### SUMMARY OF THE INVENTION

An objective is to provide an interposer equipped with switch circuits rather than a conventional passive or active interposer, which has no such provision to facilitate with the SOC when they are integrated into one system; however, the latter has its own Built-In-Self-Test (BIST), which a subset of JTAG so called compact JTAG (cJTAG) as per IEEE1149.7 standard that requires only two TAP lines, i.e. TCK and TMS, instead of all five TAP signals even though they are under the same supervision of a common JTAG controller. In the application of mixed functionalities such as a server based CPU up to 16 cores are integrated with an array of GPU's, not only creating forbidden processing power but also introducing cross-talk related latent faults besides manufacturing defectives; ideally they are tested by the JTAG and cJTAG coherently, but it is difficult to do so on the same platform due to different protocols and formulas, unless to explore the possibility of using two of four TAP Ports based Quad-POD, through a selection of two channelized ports, distinguished by two directional paths such as TAP-X and Y, and they are switched by a set of MUX/DeMUX based mechanism, steered by a software driven system so called Inter-Integrated Circuit bus (or referred herein as I²C or I2C bus) by means of two strobe lines in the case of SCL and SDA, and these two lines direct them to reach predetermined locations in light of their registered digital addresses, resulting their picking and chosen through the software based control and command.

As stated in the above paragraph, Para. 10, TAP-X and TAP-Y are configured to service either a SOC or MCU under testing per the cJTAG or JTAG standards, and either one could be the master, to direct its slaves based chiplets under boundary scan tests, once passed the Infrastructure and Interconnection tests, following the subsequent cluster test on memories, and the cluster test as stated below in extension to their related daisy chains through a software based steering mechanism to choose and pick a targeted die under test.

Another objective is to provide a switch mode based interposer which utilizes a twin-head based Test Access Path (TAP) in two separate channels running either normal Boundary Scan Test (BST) for the chiplets and/or for System-On-Chip (SOC) in the application of the Built-In-Self-Test (BIST) within the chip through TAP-X, and while the TAP-Y is idled, as stated below.

Still another objective is to provide the upper deck based interposer, that is facilitated with a set of MUX and deMUX to switch perspective channels, steering the test paths into clockwise or counterclockwise orientations along the daisy chains, and which have the daisy chains channelized into BIST at one time, depending on the switch in selection of a pair of TAP-X and Y by the JTAG controller under supervision of the JTAG based Provision System.

Yet another objective is to provide an upper deck based interposer to conduct the boundary-scan requested Infrastructural and interconnection tests on each chiplet, since they are most likely a boundary scan compatible IC with its own BSDL file, and their ID code assisting the upper deck based interposer to recognize chips on the chain, and these ID's are useful to identify chiplets related locations on the interposer, to differentiate that lower deck related substrate that only carries memory chips.

Yet another objective is to provide a lower deck based substrate disposed below the upper deck based interposer, which substrate may be populated with a suite of cache memories that may be stacked-up along with other programming chips such as Flash, SRAM and EEPROM, etc., on the substrate are to be tested by the logic cluster testing to check the connectivity between boundary scan pins and non-JTAG logic, a high-level modeling brings C-like flow control and expressions to the development of test models for non-JTAG devices with respect to their data, address and control buss, and the same buss are applicable to In-System-Programming (ISP), not only accommodating system software but also given data base storage.

According to one aspect of the invention on the interface subject to a unique unification between the interposer and substrate joined by Under Bump Metallization (UBM)—an advanced packaging process that involves creating a thin film metal layer stack between the integrated circuit (IC) or copper pillars and solder bumps in a flip chip package by DuPont, and they are designed by the JTAG based netlists which link the upper and lower deck according to the schematics, and this schematic providing signal based pins like a UBM checked and verified by the JTAG based interconnection test to diagnose potential defectives related to manufacturing defectives such as open, short, bridging and bridging, etc., on a test vector based Truth Table Report (TTR) to provide the MCM with further trouble-shooting on per pin and net based analysis.

The present invention provides a self-test method for testing a group of unknown dice in an MCM by a switch-mode based interposer using a unique self-test architecture that assigns a pair of indexed test heads, which steer test signals through a maze-like interposer and substrate architecture, organized in such way is that they are tested by cJTAG and JTAG on the interposer for the SOC and Chiplets, while the substrate on the lower deck carrying memories chips only applied with cluster test and ISP solely. This unique approach not only solves fan-out problem but also takes care of heat transfer in the case of both upper and lower decks are made of silicon based material which have identical thermal coefficient.

Unlike the standard boundary scan test that uses five TAP signals (TDI, TDO, TCK, TMS, TRST), this newly developed method only employs two of the five TAP signals (TDI/TDO) in series, and TCK, TMS, TRST on parallel buss, and they are channelized and switched for different chips under BST or BIST depending on the selection of either cJTAG or JTAG.

Two daisy chains are ported into two reversely directed paths, and they are intersected at the center-cross point, which allows these two paths switched at this point, by means of a set of 4:2 and 2:4 Multiplexed and De-multiplexed (MUX/DEMUX) scheme, their identified ports in a series of 1 to 4, through a TI based technique, it is to compare and select I²C switches and multiplexers (muxes) used to expand the capability of this control system by switching between the I2C buses ordered master and slaves.

The addressable dice are switched into forward and reverse directions in order to be cross-examined between a known one and an unknown one, depending on whether their interconnected devices if pass or fail the boundary scan test in a decision making process, intelligently at the JTAG controller.

Unique conditional tests are directed towards multiprocessor based CPU and its associated cache memories such as DDRs. This permits flip chips to be diagnosed under stack-up condition based on the stated schematics and netlists, ranging from the upper to lower deck, through two tier based systems, one is the BIST and the other one is BST while the BST offering both Infrastructure and Interconnection tests beside the cluster tests for non-boundary scan based memories on their common buss such as data, address and control, for ISP as well on the substrate systematically.

To make a switch-mode based interposer, this method may utilize semiconductor back-end process with design in a CMOS based Mux/DeMUX to select an individual die under testing without any modification to each IC in VLSI design, since they usually belong to a separate fab process, no need for expansive Automatic Test Equipment (ATE) that was typically used.

In principle, the steering mechanism is a quad bidirectional translating the switch controlled via the I²C bus, and the SCL/SDA upstream pair fans out to four downstream pairs, or channels. Any individual SCL/SDA channel or combination of channels can be selected, determined by the contents of the programmable control register with four interrupt inputs, and one for each of the downstream pairs, are provided in case of one interrupt output acting as an AND gate of the four interrupt inputs.

As was stated above, if an interrupt is generated by any device, interrupt output is driven by Low. The channel does not need to be active for detection of the interrupt since a bit is set in the control register, synchronized by the JTAG based TCK, also prevail to the need of BIST for the SOC as was mentioned above.

The above provides a choice of testing between the upper deck based Chiplets testing and the lower deck based memory based cluster testing and programming. In other words, this system intelligently uses the above said Mux/DeMux, with either a I²C based switch or Mux/DeMUX, similar to a gear train controlled by the I2C software and commanded by the JTAG controller.

In a presently preferred embodiment, the present invention provides a switch-mode interposer arrangement for boundary-scan testing of a Multi-Chip Module (MCM) having a System-On-Chip (SOC), a Microprocessor Control Unit (MCU), and multiple chiplets based devices including central processing units (CPUs), graphical processing units (GPUs), and/or memory devices disposed on a stacked or two-tiered interposer-substrate system. The SMI includes (a) a twin Test Access Port (TAP) operatively connected to a JTAG controller and configured to transmit test data in one direction defined as TAP-X and an opposite direction defined as TAP-Y along an Inter-Integrated Circuit (referred herein as I2C or I²C) bus connected with the SOC, the MCU and the multiple devices, the test data being formatted pursuant to IEEE 1149.1 (i.e. JTAG) or IEEE 1149.7 standard (i.e. cJTAG); and (b) a Mux/DeMux switch mechanism connected to the twin TAP and the I2C bus and responsive to the SOC or the MCU for selective switching of the test data along either the TAP-X or TAP-Y direction to a predetermined port associated with one of the multiple devices in the MCM.

In one embodiment, the Mux/DeMux switch mechanism is responsive to the MCU to direct the test data from TAP-X to a second set of the CPUs, GPUs, and/or devices through another predetermined port associated with a second set of the CPUs, GPUs and/or devices. Otherwise, the SOC on the TAP-Y is idled for Built-In-Self-Test (BIST), since it is not associated with the chiplets of CPU and or GPUs.

In another embodiment, a Test Mode Select (TMS) pin and a Test Clock (TCK) pin for transmitting the test data through TAP-Y and outputted to the SOC for conducting a Built-In-Self-Test (BIST) independently, and a parallel buss for transmitting and receiving the test data from the SOC in accordance with IEEE 1149.7 standard (i.e. cJTAG).

In still another embodiment, the I2C bus includes a Serial Clock Line (SCL) and a Serial Data Line (SDA) for switching and multiplexing test requirements for either the MCU or the SOC, whether the boundary scan test or BIST applied to either the MCU or SOC but not both, and the MCU is applicable to the chiplets and their respective associated CPUs, GPUs and/or devices.

In yet another embodiment, the I2C bus is responsive to the SOC and MCU to selectively transmit test data pursuant to IEEE 1149.1 standard or IEEE 1149.7.

In yet another embodiment, the I2C bus includes pull-up resistors to selectively bypass the devices not under testing, i.e., calling upon their assigned address at one of two daisy chains whether it is switched to TAP-X or Y on ports, or multiplexed on chains, and located at addresses.

There is provided a method for boundary-scan testing of a Multi-Chip Module (MCM) having a System-On-Chip (SOC), a Microprocessor Control Unit (MCU), and multiple chiplets based devices including central processing units (CPUs), graphical processing units (GPUs), and/or memory devices disposed on a stacked or two-tiered interposer-substrate system, comprising: (a) configuring a JTAG controller-based Test Access Ports (TAPs) to transmit test data in one direction defined as TAP-X for a TAP-X based daisy chain and an opposite direction defined as TAP-Y for a TAP-Y based daisy chain along with an Inter-Integrated Circuit (I2C) bus connecting the SOC, and the MCU and the multiple devices, the test data being formatted according to IEEE 1149.1 (i.e. JTAG) or IEEE 1149.7 standard (i.e. cJTAG); and (b) switching by using a Mux/DeMux switch mechanism connected to the twin TAP and the I2C bus and by responding to the SOC or MCU for selective switching the master or slaves chips of the test data along either the TAP-X or TAP-Y based daisy-chains, to a predetermined port associated with one of the multiple devices in the MCM.

According to another embodiment, the IC bus not only switches and multiplexes but also directs the test data to a specific port in the selection of a specific logic address at the chosen device under testing and/or programming, to reduce system loading in resource sharing if only depending on the SOC based BIST which resources are allocated to by Logic-BIST or Memory BIST, taken from the system memories, at initial and final testing stages, leading the internal memory and external memories in searching of kernel mode or user mode whether on-line or off-line thereby providing them a chance to operate in either mode with constraints from both modes.

According to yet another embodiment, the memory mapping, the chiplets based CPU and inherited boundary scan programming capability in accessing of data, address and control buss to read, write, erase, blank check and verify in addition to running cluster tests for these cache memory based DDRs.

According to yet another embodiment, the cluster tests are applicable to the cache memory based DDRs usually stack-up in double-deck like assembly, causing difficulty to validate them as a set of Known-Good-Dies, and this innovative method solves this problem by using cluster test even though they are not boundary scan compatible devices but can be selected through the address buss along with their chip enable pins running under cluster testing.

According to yet another embodiment, the lower deck assembly integrated with cache memories, SRAM, Flash memories and EEPROM, and other memory devices, tested and programmed by a consolidated schematics in assistance of their boundary scan based netlist as well as a Bill Of Material (BOM), to execute BST, BIST and Cluster Tests throughout the system according to IEEE1149 standard.

According to yet another embodiment, the present invention provides an innovative method in making Known-Good-Dies within an MCM by means of self-testing the SOC through the BIST, and the CPU and GPU by BST, and their associated memory chips by the cluster test besides in-system-programming all inclusively.

According to yet another embodiment, the present invention solves the chiplets related problems, mainly they are bare dies which are blind and unknown to their mother board, and this method validates and qualifies them beyond the functional test before and after their manufacturing process.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

In the drawings:

FIG. 1 schematically illustrates a monolithic assembly comprising two chip as the master to lead a suite of chiplets and memories residing on their respective interposer and substrate under testing to determine whether they are good or bad dice after boundary scan diagnostics, with the dice under testing itemized on a table alongside their assembly so is the Bill Of Material (BOM) as is common engineering practice;

FIG. 2 illustrates a schematic as part of the design for test in [Para 26] and this schematics is depicted with nets related interconnections and their associated nodes comprising with innovative test approaches involved in twin-TAPs based daisy chains, as per TAP-X and Y deployed terminals from the JTAG's quad POD which is part of the JTAG controller, and illustrates a switching mode based mechanism steering through a I²C based switch or Mux/DeMux logics to steer and alter the test paths at the cross-over center, wherein the daisy chains making decision is made to pick and choose the selected die according to its digital address embedded in the register of the master and slave chips;

FIG. 3 is a cross-section view of the two tiered switch-mode interposer system on a double-decked platform assembled with the interposer on the top and substrate on the lower part of this super structure, to illustrate the flow of the system in a diagram, representing twin-TAPs, double daisy chains, and programming lines of the I²C bus in relation to their respective dice under testing;

FIG. 4 depicts the system in an arrangement of two-track based scheme through channelizations in opposite directions as shown, and this rail road like tracking systems, passing through different stations, one is made for JTAG and another is for cJTAG, they are designed in parallel paths but intersecting at their cross point as shown in FIG. 2. to approach the interposer and substrate;

FIG. 5 is a system assembly related block diagram that consists of essential elements of the upper deck involved in SOC and MCU as one of the master in association with their slave chips such as CPU or GPU based chiplets, specially designed with the TAP-X for cJTAG and the TAP-Y for JTAG;

FIG. 6 is a flow chart to illustrate how the system operating in a way testing of boundary scan of chiplets based Infrastructure test and Interconnections on data, address and control buss, besides cluster testing and programming of memory chips; and

FIG. 7 is a table showing the results of the diagnostics tests run by the inventive switch-mode interposer.

### DETAILED DESCRIPTION OF THE PRESENTLY PREFERRED EMBODIMENTS

Unlike the traditional Joint Test Access Group (JTAG) that allows one daisy-chain passes through a TAP port, one at a time, the inventive Switch-Mode Interposer (SMI) self-test system and method permit multi-drop or cascaded ports to branch out a daisy chain into different channels, in the event a dedicated ID code is not available. This method assigns each IC under testing a logic address at their respective locations in the absence of a daisy-chain, and enable testing of a faulty device by the IEEE1149 specified Infrastructure test and subsequent Interconnection tests in an extension of cluster testing of memory chips.

This system and method is aided by an advanced self-testing system which orders the pairing and looping of TDI/TDO, starting from a “Scan Bridge” based Test Head which is a technique to expand one TAP port to another by sharing each other's registers from one port to another by the controller ordering which TAP based port is active and to run independently or dependently in different directions, clockwise or counter-clockwise, whether it is to run BST or BIST on the SOC, and the decision is made by the JTAG controller based software tools.

This innovative method applies a mapped register table in a matrix, akin to map “coordinates” of the dice, which are enabled to provide the pre-defined logic location of the die under testing in the following ways:
1. The Master's Serial Vector Format (SVF);
2. The Slaves' IC bus, e.g., a CPU;
3. The strobes of “select” and “de-select “at the addressable Latches and MUX/DeMUX; and
4. Addressed bus related to Dynamic Random Access Memories (DDR).

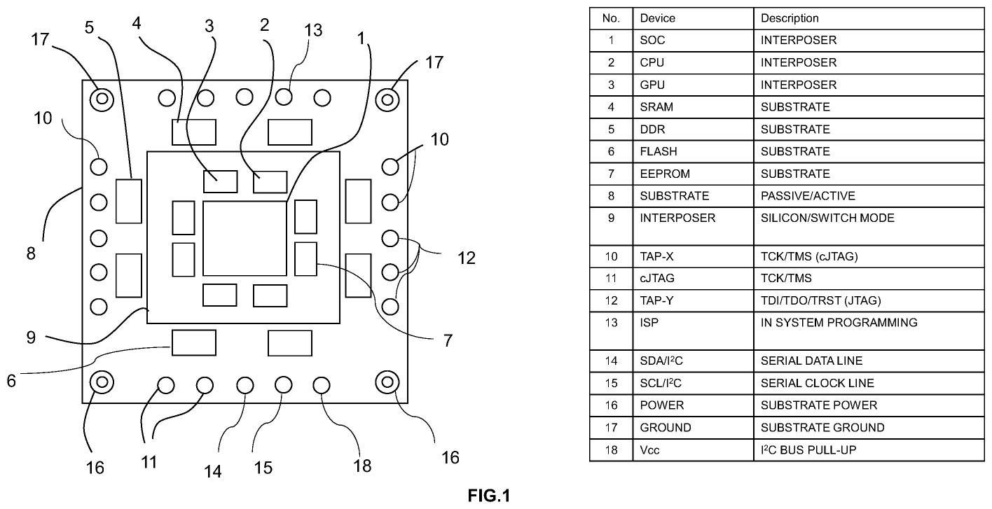

FIG. 1 depicts an MCM enabled to self-test itself via a switch-mode based interposer (SMI), combined with logic control circuits to drive and sense boundary scan cells at their logic locations of their residence die.

The SMI is configured as a tester to test devices disposed on the MCM, comprising a plurality of chiplets and their associated memory chips to be finally integrated as a system in a module.

An important feature of this novel approach is the ability to design a logic map comprised of registers that addresses each logic location, thereby allowing the die to be tested blindly without knowledge of an ID code as required by present testing technologies. By the same token, for non-boundary devices like the DDRs 9-16, which have no ID codes any way, they can be tested functionally in a similar manner. Depending on their addressable buss, once their related CPUs are recognized, the DDRs are identified as extensions through Data, Address and Control buss, thereby allowing the bus signals to be tested functionally.

In a complex silicon interposer based MCM, a faulty die is often induced by thermal stress and related environmental issues such as, for example, (1) flip chip based bumping process like C4, etc.; (2) cold or hot soldering generating open or shorts on stack-up dice; and (3) discontinuity and/or cross-talks during high speed routines.

The invention solved these problems on a silicon interposer level, and could improve the yield of MCMs. There are three critical elements used for building this advanced SMI system: (1) a transparent scan bridge to instruct TAP-X or Y of test heads, (2) Mux/DeMux to selectively steer these test heads into quadrant ports (e.g., Port 0, Port 1, Port 2, and Port 3) and (3) through a cross-over bus mastered by I2C protocol to assign new path towards each slave, i.e., devices under test.

MCMs are notoriously difficult to debug if an unknown die is present because (1) there is no label on each chip, (2) bare dice are made to flip-chip with hidden bumping, and (3) they are blindly assembled together.

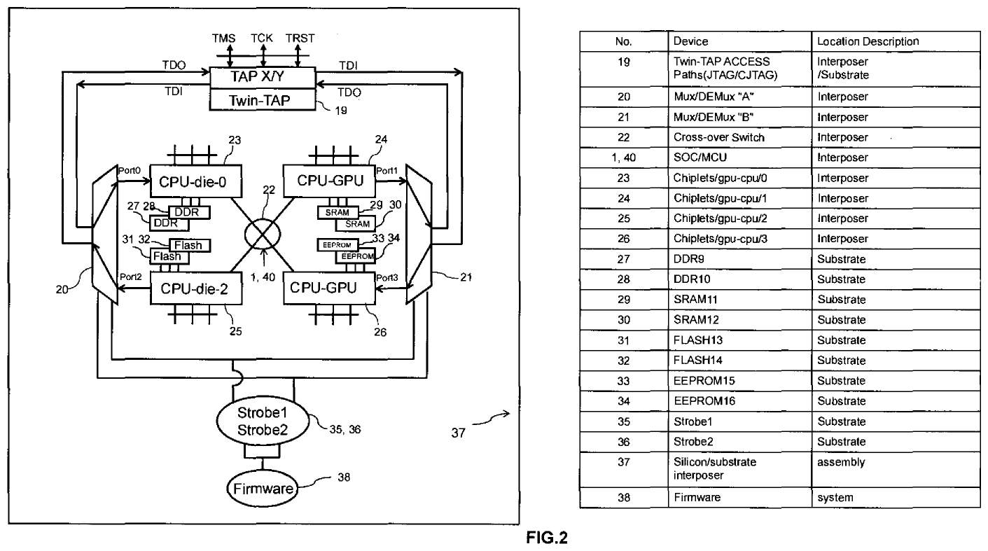

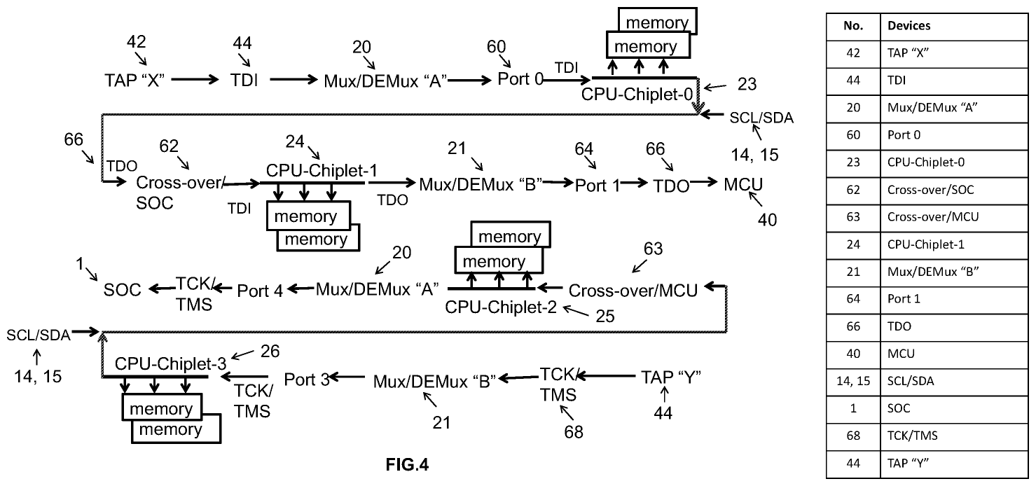

The present invention advantageously provides a logic system for dice to address their own locations in an MCM through an embedded registers system to guide the TDI/TDO test signals to behave like a pair of index fingers pointing to the die under test at specific port and address. This built-in steering system embedded in a passive or active interposer provides a novel approach for the Design For Testing (DFT) at die level and which uses module schematics based/required netlist to interconnect all pins and micro bumps of dice in an MCM. This new method is achieved by selectively steering signals through a pair of TDI/TDO instead of all five TAP signals (TDI, TDO, TCK, TMS and TRST) to a die under test at its corresponding local locations according to a look-up table through multiplexing and de-multiplexing plural TAP ports. These ports are switched at a cross-over point, either in a forward or reverse direction in two way traffic, as shown in FIGS. 2 and 4.

A commercially available DS26900 chip may be used to mux the master channels from 4:2 to 2:8 slaves channels, controlled by GPIO and SSPI terminals as a self-guide system which is switched by I2C firmware through Serial Data Line (SDA) and Serial Clock Line (SCL) bus lines.

The first step is to research an advanced architecture in lieu of the traditional approach that requires a Boundary scan ID code to indicate which chip is under test. An MCM only carries bare dice without noticeable die markers, thereby making test paths dependent Daisy Chains indispensable during trouble-shooting and diagnostics. This is made worse when a boundary scan required “Interconnections Test” is only partially performed by the “Infrastructure Test”, rendering the bad die indeterminate as to its causes of failures, and in the case of bumped dice the failures become undetectable. This occurs because a silicon interposer has no power and ground planes to support complicated Interconnection test through schematics based netlist on those dies.

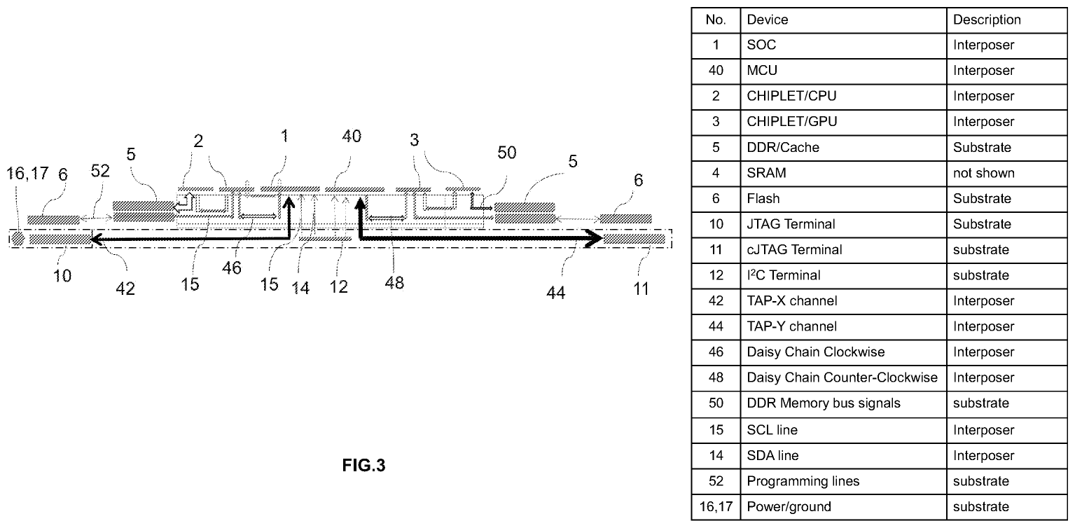

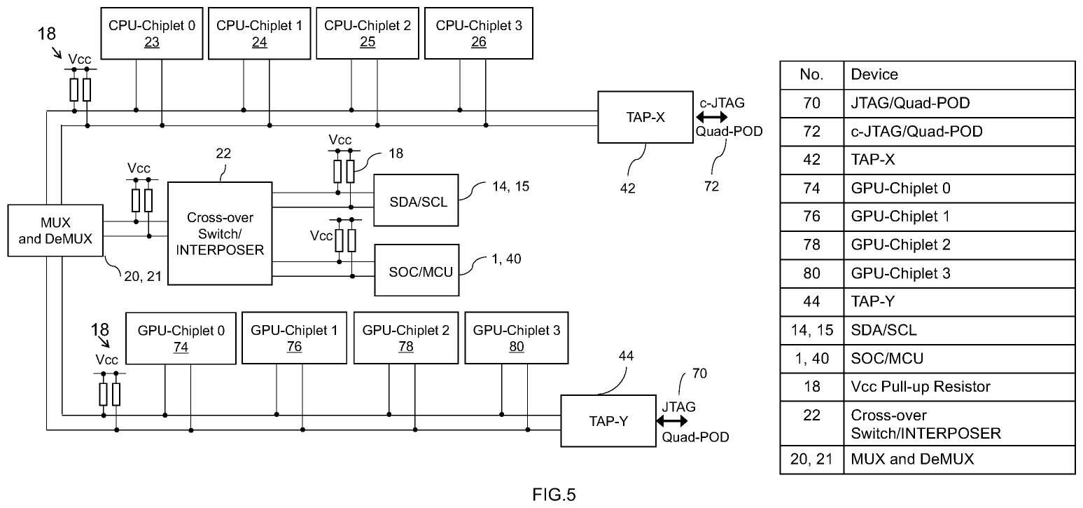

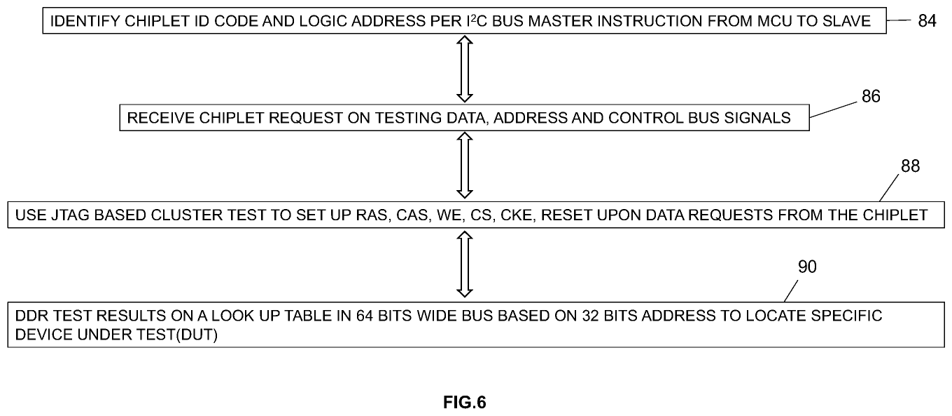

Thus, this innovative test system equipped with a twin-headed, double-deck based two-tier platform, comprised of dual test paths which are coupled with the I2C bus, of which the I2C stands for “Inter-Integrated Circuit,” and which was first introduced by the Philips semiconductors in 1982. The I2C bus consists of three data transfer speeds such as standard, fast-mode and high-speed-mode. Thus, to qualify these unknown dice under test by JTAG (named after the Joint Test Action Group is an industry standard for verifying designs and testing electronic assemblies after manufacture) or cJTAG which is the new IEEE 1149.7 standard referred to as Compact JTAG or cJTAG that has been developed to meet the ever increasing needs of testing modern electronics boards and systems in extension to the specified chiplets and their associated memory chips in bare die form. This embodiment of innovative method depicted herewith are to handle both Boundary Scan Test (BST) and Built-In-Self-Test (BIST) working coherently under one common platform which allows System-On-Chip (SOC), Microprocessor Control Unit (MCU) on the interposer along with chiplets of the Central Processor Unit (CPU), Graphic Processor Unit (GPU), etc. to be tested under deployment of the inventive switch-mode based interposer, and their associated memories such as SRAM, DDR, Flash and EEPROM, etc., are deployed on a substrate to be programmed, subsequently after the host ICs passed the Infrastructure and Interconnection Tests with them, as shown in FIG. 1. The test requires a daisy chain based system to run dice under self-testing through a master based control and command on the interposer in FIG. 2, to thereby command these two daisy chains under testing through two tracks in a rail-way like arrangement, one-way traffic is dedicated to follow the JTAG protocol, and the reverse track is a response from the System On Chip (SOC) by means of the cJTAG protocol as per TCK and TMS test signals instead of the regular five TAP signals (TDI, TDO, TCK, TMS, TRST) as shown in FIG. 3. Both tracks are requested to halt at the designated station as per assigned digital address in accordance with I2C protocol, as shown in FIG. 4. The substrate could be either passive or active or simply a Fr-4 based PCB, providing a base to carry out subsequent test and programming of memory devices such as SRAM, DDR, Flash and EEPROM, etc, via their native data, address, and control buss without demanding extra resources from the slaves of which depicted on FIG. 5, and such an unique arrangement in exercise of the chip with inherited functions in an MCM, resulting the skilled and inventive technology as shown in FIG. 6.

There is shown in FIG. 1 a monolithic assembly comprised of two chip carriers (containing dice and/or chiplets), design for test (DFT) with an interposer 9 and substrate 8, and the interposer 9 may be passive or active with Trans-Silicon-Vias (TSV) to interconnect the dice or chiplets internally and to assemble with the substrate 8 by using Under-Metal-Bump (UMB) in between, both are in-line with flip-chip process from items 1-3 (i.e. SOC 1, CPU 2, and GPU 3) to items 4-7 (i.e. SRAM 4, DDR 5, FLASH 6, and EEPROM 7) as referenced and defined in FIG. 1, respectively. Herewith TAP-X terminal 10 representing one of the twin-headed Test Access Paths (TAP) as the JTAG based daisy chain as compared to cJTAG terminal 11, and which is managed by a standard I2C bus along with TAP-X for cJTAG and TAP-Y as the cJTAG plus Vcc 18 through two serial lines which are the Serial Data Line (SDA) 14 and Serial Clock Line (SCL) 15 to provide the In-System-Programming (ISP) functions as per In-System Programming 13, aiming at the SRAM 4, Flash 6, EEPROM 7, etc., besides DDRs 5 to cache CPUs 2 and GPUs 3, also including power supply 16, ground terminals 17, and Vcc 18 on the substrate 8 to complete an MCM embedded with its self-test-ability by JTAG, cJTAG and I2C provisions.

FIG. 2 is a diagram showing the monolithic assembly of FIG. 1 configured to run BST and BIST coherently in the application of a twin-head based Test Access Paths (TAP). The devices in the SOC 1 are daisy-chained and TDI and TDO data signals circulating either clockwise or counterclockwise as shown, and they are channelized into four quadrants at Port 0, Port 1, Port 2, and Port 3, then muxed or demuxed into separate channels towards devices under test, but switched at the cross-over center crossing point where the master chip is located, which may be a MCU 40 or SOC 1, which is the master to run slave chips on the I2C bus. The bus protocol (or so called the bus master) is used to select slaves chiplets along the tracks via a daisy chained boundary scan chips; however, the memory chips are not under supervision of the I2C protocol since they are requested by the host chip such as the CPU or GPU in this case.

As shown in FIG. 2 this test system has twin TAP heads 19, representing the method facilities of both JTAG (IEEE1149.1) and compact JTAG, i.e. cJTAG (IEEE1149.7), and which are switched by a set of MUX/DeMUX-A 20 and MUX/DeMUX-B 21, of which under control and command from the master chip SOC 1/MCU 40, pointing the arrow head towards the chiplets under testing 23-26, which are integrated on the interposer/substrate assembly 37 wherein memory dice, including the cache memories DDRs 27, 28, SRAMs 29, 30, Flash memories 31, 32, and EEPROMs 33, 34. These memory devices are tested and programmed by their host chiplets (e.g., CPU 2), and the host IC's are chosen by the strobe signals from Strobes 35 and 36 (shown as Strobe 1 and Strobe 2 in FIG. 2), to generate the digital address by the I2C protocol via the firmware 38, usually written in serial vector format (SVF) in accordance with IEEE1149.1.7 specified protocols.

FIG. 3 shows an exemplary cross-section view of an embodiment of a monolithic assembly of the present inventive method, which is based on the following system integration: the devices assembly is configured as a two-tier system running both BST and BIST, residing on double-decks (i.e., substrate and interposer layers), with the upper deck or tier being the interposer and the lower deck or tier being the substrate, with the twin-test heads 19 circulating around the two-tier system from top to the lower deck and vice versa to comprise a 3-D platform which is enabled to be configured into various applications. A generalized approach is to accommodate international standards ranging from JTAG, cJTAG to I²C protocol, which is embedded into both the interposer and/or substrate depending on how many memory chips or devices are employed in the system. The benefit of that is the degree of freedom offered to the system designers when dealing with a CPU based Chiplet system or a GPU based Chiplet system, or both to be a data-center related Artificial Intelligent (AI) server. It's expandable from a CMOS based Multiplexer design of an active interposer or simply a thin-film rerouting based passive substrate, and this method is not limited to any of such approaches since their architecture is generic.

This inventive test system is set up to begin with dual master control chips, perhaps one is the System-On-Chip (SOC) 1, and the other one is Microprocessor Control Unit (MCU) 40 which is commonly applicable to machine controls, and both usually can be accessed by an I²C bus 12, causing the master chip (e.g., SOC or MCU) to send command to the slave chip to request and to be acknowledged by the slave chips which may be the CPU 2 or GPU 3 chiplets in this case. Besides, these master chips are typically configured to support IEEE1149.7 standard to facilitate JTAG's Test Access Paths (TAP) including TAP-X 42 and TAP-Y 44 respectively on boundary scan daisy chains 46, 48 respectively at JTAG and cJTAG. This allows the system to exercise boundary scan test on daisy chained chips, such as CPU 2 and GPU 3 which are enabled to take instruction and data inputs once it is called upon by the master chip at its unique address. This advantageously allows the diagnostic test system to recognize an unknown module populated with bare dies based flip-chips, to qualify them as a group of Known Good Die (KGD) in making an MCM (not shown), while the TAP-X 42 is assigned to engage with MCU 40 to run BST through JTAG 10, and TAP-Y 44 is assigned to engage with SOC 1 to run BIST through cJTAG channel 11, both channels circulating in reversed directions and intersecting at their cross-over center 22 at the MUX/DeMUX terminal 20, 21 via two command lines which are SCL 15 and SDA 14. The commands, preferably generated by the JTAG controller, direct the master chip to instruct a specific slave, e.g., a chiplet located at its logic address. However, this method does not need not need the switching mode interposer 9 to call upon DDRs 5 since they are interconnected by their host buss such as data, address and control buss, and tested by JTAG's cluster test associated with their hosted CPU 2 and GPU 3 chips; this is same for the SRAM 4, in addition to the Flash memory 6 in order to make up the In-System-Programming (ISP) 13 for erase, blank check, write and verify routines, etc. This test method provides distinctive advantages to run so called Memory BIST and Logic BIST related to the signature analysis within the frame work of an MCM which has its own power supply and grounds on item 16, 17.

Unless a new architecture is developed by using JTAG based Netlist (so called JTN), the present method allows one to test each die individually through its I/O pins associated boundary scan cells, to thereby drive and sense each die by Test Input and Output Data (TDI/TDO) only and not through its control signals (TMS, TCK and TRST) in parallel bus. This method reduces routines greatly to relax the limitations on silicon layouts, floor planning as well as logic gating as compared to the conventional method of piping in and out all five TAP signals to each die. This method is diagrammatically illustrated in FIG. 4 for an MCM integrated with plural chiplets and DDRs of FIG. 1

FIG. 4 is an illustration of such a system interacting in synchronized chain reactions, i.e., a conjugation operating on two tracks TAP-X and TAP-Y, and guided by their steering mechanism in two opposite directions: one way links to a destination which is the SOC 1 to be tested by BIST, and the other one links to another destination, i.e., the MCU 40 which is to be tested by BST, and they shall intercept at the cross-over center whereat the I2C bus master makes decision based on a set of MUX and De-MUX to pick and choose the ideal track depending on the I2C bus selected address, as well as the chip embedded ID code. Once a chiplet responds to the request, the rest are on standby or pulled up at high impedance for the selected device under testing of its infrastructure and interconnections, thus fully utilizing the functionalities of the I2C bus's abundant features and also incorporated with the JTAG's ID coding from the BSDL file, to exert the switching circuits by these two strobe lines, i.e., SCL 15 and SDA 14 as shown in FIG. 3.

FIG. 4 illustrates the twin-TAPs for SOC 1 and MCU 40 via the I2C bus which has two strobe lines as per SCL and SDA 14, 15. As shown, TDI 44 is inputted to TAP “X” 42, and selectively switched by Mux/DeMux A 20 to Port0 60 for CPU-Chiplet-0 23 and memory devices to TDO 66 and through the cross-over/SOC 62 and inputted (as TDI) to CPU-Chiplet-1 24 and associated memory devices and then to Mux/DeMux B 21 and then selectively routed to Port1 64 and outputted as TDO 66 to MCU 40 based on the JTAG's serial bus pursuant to IEEE 1149.1 to test MCU 40. In contrast, parallel bus based cJTAG standard pursuant to IEEE 1149.7 employs test signals TCK/TMS 68 to run BIST on SOC 1 for signature analysis. As shown, these test signals inputted at TAP-Y are multiplexed at Mux/DeMux “A” 20 and switched to Port3 for CPU-Chiplet-3 26 and associated memory devices and at their Cross-Over/MCU 63 and through cross-over/MCU 63 and inputted to CPU-Chiplet-2 25 and associated memory devices and then to Mux/DeMux A 20 and then selectively routed to Port4 and finally to SOC 1.

In summary, FIG. 4 illustrates a double-looping indexed TDI/TDO running in two directions, either clockwise or counter-clockwise starting at the TAP-X or TAP-Y and are channelized by TAP in either X or Y direction, branching out to separate ports, and switched by a pair of Mux/DeMux to locate a chosen port. Once the test signal enters the networked chiplets, it is switched to an individual die and guided around a cluster of dice, to avoid a bad one, and then selectively to a second chiplet.

FIG. 5 illustrates the system design of a combined JTAG/cJTAG arrangement enabled or facilitated by the I2C bus. Mainly the JTAG/cJTAG test signals are directed by the master chips which are equipped with boundary scan cells in accordance to their Boundary Scan Descriptive Language, a subset of VHDL, and it's the basis for JTAG's test development as well as the bus master based software of I2C to create a digital address for selected Chiplet via two strobe lines, i.e., the serial clock (SCL) and serial data (SDA) related protocol originated from the SVF script. The JTAG controller here issues either 5-TAP signals on the serial bus for boundary scan testing of the Chiplets or issues only 2-TAP signals which are TCK and TMS on the parallel bus to run Built-In-Self-Test (BIST) for the SOC 1, and the modem SOC often part of the system chip in an MCM to be self-tested by two strategic deployments as per L-BIST and M-BIST when the other chips are by-passed conveniently according to the IEEE1149 standard.

FIG. 5 also illustrates the JTAG, cJTAG and I2C bus working coherently under system command from the JTAG controller using JTAG Quad-POD 70 and cJTAG Quad-POD 72 through SDA 14 and SCL 15 per I2C 12 in FIG. 3, to approach the destined MCU 40 or SOC 1. Nevertheless, either way is necessarily to be chosen under the two-paths scenario, i.e., TAP-X 42 or TAP-Y 44, which may be selected for testing Chiplets 23, 24, 25, 26, 74, 76, 78, 80 and/or SOC 1 and MCU 40 on the basis of regular BST or optional BIST on the SOC 1. Thus, this system is designed to have both via a switch mode interposer through a set of MUX/DeMUX 20, 21 to switch over at the cross-over switch/interposer 9 by an I2C based bus master facilitated with pull-up resistors 18 at the cross-over point. The system intelligently uses JTAG based by-pass mode to consider either CPU Chiplets 23, 24, 25, 26 or GPU Chiplets 74, 76, 78, 80 in the MCM designs related to the interposer 9, in extension to the cache memory based DDR's, along with user mode coding and kernel mode coding required SRAM 4, Flash memories 6 and EEPROM 7 as well.

As discussed above, the inventive self-testing system is capable of programming the chiplets related memories as well system software required coding by the JTAG bases In-System-Programming (ISP) on the top deck part of the assembly, i.e., the interposer atop the substrate and populated with a suite of memory chips. The advantages of the self-testing system include minimization of resources required by an MCM and thus minimizing next tier operations on the substrate as if in a monolithic chip. Such an innovative approach is depicted by the flow chart in FIG. 4.

FIG. 6 is a flow chart of the inventive self-testing process using the switch-mode based interposer. In Step 84, the system identifies chiplet ID code and logic address per I2C bus master instruction from MCU to slave. In Step, 86, the system receives chiplet request on testing data, address and control bus signals. In Step 88, the system uses JTAG based cluster test to set up RAS, CAS, WE, CS, CKE, RESET upon data requests from the chiplet. In Step 90, the system locates Device Under Test (DUT) using DDR test results on a look up table in 64 bits wide bus based on 32 bits address.

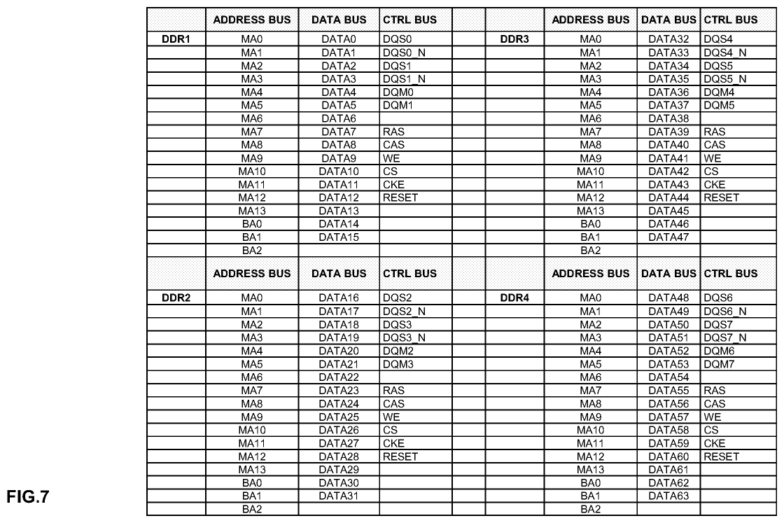

FIG. 7 shows the results to validate the present inventive arrangement and methods in which DDR's are stacked-up in two banks, accesses 32 bits address lines to read and write 64 bits data under the control lines requested by the main CPU/GPU which is chosen by the I2C bus on a dual track based approach. Such a provision gives way to test and program memory specific applications, such as the kernel mode driver, user mode driver, as well as Operating System (OS) at their perspective address. According to this innovative method, the system has achieved a boundary scan based truth-table (TTR) in reference to the MCM based schematics along with its derivative as to the netlist, assisted by the Chiplet's BSDL file. This system is capable of running its own test on the shared buss such as data, address and control buss, to diagnose bugs as well as defectives associated with the chiplets and memories under test in association with their pins if open, or nets if shorten or bridged; These defectives, which may be resulted from bumps on the flip-chips encountering cold or hot soldering adjacent the isolation layer such as the polyimide based dielectric layer which experienced thermally induced stresses causing premature fatigue and crack growth, etc. Defectives in addition to the system enclosed SOC chips may also suffered from the latent faults due to internal cross-talk effects on the peripheral or in the cores, all of which can be tested by the optional JTAG's core-commander as part of series of diagnostic solutions provided by this inventive test system.

In conclusion, the present invention is a novel SMI self-testing of an MCM. It innovatively applies a look-up table to address a registered die under testing boundary scan devices in extension to non-boundary scan ICs such as the DDRs, and still in compliance with the Joint Test Access Group (JTAG) standard as per IEEE 1149 required protocols.

To achieve the set objectives of SMI, we have developed a brand new architecture that is indifferent to the traditional daisy-chain based infrastructure that links up ID codes in order to recognize each device and which is serially connected through Test Data Input (TDI) and Test Data Output (TDO) along with Test Mode Select (TMS), Test Clock (TCK) and Test Reset (TRST) bused arranged in parallel. Instead, we only use TDI and TDO as a pair of index fingers guided through a steering mechanism that crosses a group of control logics including a plurality of multiplexer and de-multiplexer, to differentiate their master and slave at specific ports, using firmware to redirect the path toward a targeted die, which may be a specific chiplet-based CPU in extension to its cache memories. These devices are thus tested by JTAG standard software tools in light of Design For Testing practice.

The most troublesome dice from a testing perspective have been the flip-chips based DDRs, since they are stacked up in decks by micro-bumps assembly, and it is difficult to dissipate their heat to the adjacent power hustler, i.e., CPU, failures occasionally occur at micro-bumps due to heat transfer induced fatigue and cracks.

In case the CPU has passed the boundary scan test but the DDR does not, this inventive Switch Mode Interposer system allows trouble-shooting of failure modes per net for the devices, and to debug the failures such as open, short, bridging, etc. related to the pin. On the other hand, if the DDRs are good according to the test, then it is interpreted to mean the CPU is able to emulate data, address and control signals to and from the DDRs with respect to their connected boundary scan cells.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A switch-mode interposer arrangement for boundary-scan testing of a Multi-Chip Module (MCM) having a System-On-Chip (SOC), a Microprocessor Control Unit (MCU), and multiple chiplets based devices including Central Processing Units (CPUs), graphical processing units (GPUs), and/or memory devices disposed on a stacked or two-tiered interposer-substrate system, comprising:
(a) A twin Test Access Port (TAP) operatively connected to a JTAG controller and configured to transmit test data in one direction defined as TAP-X and an opposite direction defined as TAP-Y along an Inter-Integrated Circuit (I2C) bus connected with the SOC, the MCU and the multiple devices, the test data being formatted pursuant to IEEE 1149.1 (i.e., JTAG) or IEEE 1149.7 standard (i.e., cJTAG); and
(b) a Mux/DeMux switch mechanism connected to the twin TAP and the I2C bus and responsive to the SOC or the MCU for selective switching of the test data along either the TAP-X or TAP-Y direction to a predetermined port associated with one of the multiple devices in the MCM.

2. The switch-mode interposer arrangement of claim 1, wherein the Mux/DeMux switch mechanism is responsive to the SOC to direct the test data from TAP-X to a first set of the CPUs, GPUs and/or devices through a predetermined port associated with the first set of the CPUs, GPUs and/or devices and then to the MCU in accordance with IEEE 1149.1 standard (i.e., JTAG) defined ports of a Quad POD.

3. The switch-mode interposer arrangement of claim 2, further comprising a Test Data In (TDI) pin for transmitting the test data through TAP-X and receiving a Test Data Out (TDO) pin from the MCU in a serial buss in accordance with IEEE 1149.1 standard (i.e., JTAG).

4. The switch-mode interposer arrangement of claim 3, wherein the Mux/DeMux switch mechanism is responsive to the MCU to direct the test data from TAP-X to a second set of the CPUs, GPUs, and/or devices through another predetermined port associated with a second set of the CPUs, GPUs and/or devices.

5. The switch-mode interposer arrangement of claim 4, further comprising a Test Mode Select (TMS) pin and a Test Clock (TCK) pin for transmitting the test data through TAP-Y and outputted to the SOC for conducting a Built-In-Self-Test (BIST) independently, wherein the I2C buss is configured for transmitting and receiving the test data from the SOC in accordance with IEEE 1149.7 standard (i.e., cJTAG).

6. The switch-mode interposer arrangement of claim 5, wherein the I2C bus includes a Serial Clock Line (SCL) and a Serial Data Line (SDA) for switching and multiplexing test requirements for either the MCU or the SOC and their respective associated CPUs, GPUs and/or devices.

7. The switch-mode interposer arrangement of claim 6, wherein the I2C bus is responsive to the SOC and MCU to selectively transmit test data pursuant to IEEE 1149.1 standard or IEEE 1149.7.

8. The switch-mode interposer arrangement of claim 7, wherein the I2C bus includes pull-up resistors to selectively bypass the devices not under testing.

9. A method for boundary-scan testing of a Multi-Chip Module (MCM) having a System-On-Chip (SOC), a Microprocessor Control Unit (MCU), and multiple chiplets based devices including central processing units (CPUs), graphical processing units (GPUs), and/or memory devices disposed on a stacked or two-tiered interposer-substrate system, comprising:
(a) configuring a JTAG controller-based Test Access Ports (TAPs) to transmit test data in one direction defined as TAP-X for a TAP-X based daisy chain and an opposite direction defined as TAP-Y for a TAP-Y based daisy chain along with an Inter-Integrated Circuit (I2C) bus connecting the SOC, and the MCU and the multiple devices, the test data being formatted according to IEEE 1149.1 (i.e., JTAG) or IEEE 1149.7 standard (i.e., cJTAG); and
(b) switching by using a Mux/DeMux switch mechanism connected to the twin TAP and the I2C bus and by responding to the SOC or MCU for selective switching of the test data along either the TAP-X or TAP-Y based daisy-chains, to a predetermined port associated with one of the multiple devices in the MCM.

10. The method of claim 9, further includes the step of directing by the Mux/DeMux switch mechanism in response to the MCU the test data from TAP-X to a first set of the CPUs, GPUs and/or devices through a predetermined port associated with the first set of the CPUs, GPUs and/or devices and then to the SOC in accordance with the IEEE 1149.7 standard (i.e., cJTAG).

11. The method of claim 10, further includes the step of transmitting test data through a Test Data In (TDI) pin to TAP-X and outputting the test data to the MCU through a Test Data Out (TDO) pin.

12. The method of claim 11, further including the step of directing the test data from TAP-Y by the Mux/DeMux switch mechanism in response to the MCU to a second set of the CPUs, GPUs, and/or devices through another predetermined port associated with a second set of the CPUs, GPUs and/or devices, to decouple BIST related to the SOC in accordance with IEEE 1149.7 standard (i.e., cJTAG).

13. The method of claim 12, further including the step of transmitting the test data to the TAP-Y through a Test Mode Select (TMS) pin and a Test Clock (TCK) and outputting to the SOC.

14. The method of claim 13, further including the step of transmitting commands from the SOC or MCU to their respective associated CPUs, GPUs and/or devices using a Serial Clock Line (SCL) and a Serial Data Line (SDA) on the I2C bus.

15. The method of claim 14, wherein the I2C bus is responsive to the SOC and MCU to selectively transmit test data pursuant to IEEE 1149.1 standard or IEEE 1149.7.

16. The method of claim 15, wherein the I2C bus includes pull-up resistors and further including the step of selectively bypass devices not under testing by selectively pulling the pull-up resistors.
